(19) United States
(12) Patent Application Publication
(10) Pub. No.: US 2013/0334586 A1
(43) Pub. Date: Dec. 19, 2013

(54) NON-SELF-ALIGNED NON-VOLATILE MEMORY STRUCTURE

(71) Applicants: HSIN CHANG LIN, HSINCHU COUNTY (TW); WEN CHIEN HUANG, HSINCHU COUNTY (TW); YA-TING FAN, HSINCHU COUNTY (TW)

(72) Inventors: HSIN CHANG LIN, HSINCHU COUNTY (TW); WEN CHIEN HUANG, HSINCHU COUNTY (TW); YA-TING FAN, HSINCHU COUNTY (TW)

(73) Assignee: YIELD MICROELECTRONICS CORP., HSINCHU COUNTY (TW)

(21) Appl. No.: 13/524,058

(22) Filed: Jun. 15, 2012

(51) Int. Cl. H01L 29/788

(52) U.S. Cl. 257/316; 257/E29.3

(57) ABSTRACT

A non-self-aligned non-volatile memory structure, comprising: a semiconductor substrate; a left floating gate memory cell and a right floating gate memory cell; a control gate; and a gate insulation layer disposed among said two floating gate memory cells and said control gate. Drains of said two floating gate memory cells are connected to different voltage levels. Said control gate is over said two floating gate memory cells, to cover said floating gates of said two floating gate memory cells, so as to control said two floating gates simultaneously. Said non-self-aligned non-volatile memory structure mentioned above does not require line-to-line alignment of gates, thus reducing significantly the complexity of manufacturing process, and number of layers of photo masks required, in achieving production cost reduction.

### BACKGROUND OF THE INVENTION

1. Field of the Invention

The present invention relates to a memory structure, and in particular to a low cost non-self-aligned non-volatile memory structure.

2. The Prior Arts

Along with the progress and development of the Electronic, and Information Industries, the technology used for various electronic products are advancing rapidly. In these electronic products, memory is used to store important data. Presently, the Non-Volatile Memory (NVM) used most frequently in a memory is for example, a flash memory, that is used in large amount in handsets and digital cameras.

To be more specific, the Complementary Metal Oxide Semiconductor (CMOS) manufacturing process is now used extensively to produce Application Specific Integrated Circuit (ASIC). In the computer age of today, the Electrically Erasable Programmable Read Only Memory (EEPROM) is utilized widely in the electronic products, for its advantages of being able to be written and read data electrically as non-volatile memory, such that the data stored therein will not be lost when the power is off.

In general, the non-volatile memory is programmable, and that is used to store electric charges to change the gate voltage of the transistor in the memory, or it does not store electrical charges to leave the gate voltage of the transistor in a memory unchanged. Moreover, an erasure operation is used to remove all the electrical charges stored in the non-volatile memory, so that all the non-volatile memory returns to the original gate voltage of the transistor in the memory.

In the prior art, the non-volatile memory can be classified into two types of silicon structures, wherein, one is the mainstay Floating Gate structure, and the other is a silicon-oxide-nitride-oxide-silicon (SONOS) structure. According to researches conducted by various flash memory manufacturers, the Floating Gate structure has its limitations, for example, size of NOR chip has to be less than 45 nm, while size of NAND chip has to be less than 32 nm. Furthermore, in general, the gate of the non-volatile memory is composed of a control gate and a floating gate of equal width. Therefore, in the subsequent thermal process of NVM, additional three or four photo masks are required to meet the requirement of specification of gate line-to-line alignment. As such, that will increase significantly the number of process, complexity, and cost of manufacturing.

Therefore, presently, the design and manufacturing of non-volatile memory of the prior art is not quite satisfactory, and it has much room for improvements.

### SUMMARY OF THE INVENTION

In view of the problems and shortcomings of the prior art, the present invention provides a non-self-aligned non-volatile memory structure, to solve the problem of the prior art.

A major objective of the present invention is to provide a non-self-aligned non-volatile memory structure, that is realized through designing a control gate over a floating gate to cover two memory cells, to control simultaneously two non-self-aligned floating gates.

Another objective of the present invention is to provide a non-self-aligned non-volatile memory structure, wherein a structure is utilized that, the control gate is over the floating gate to cover the two memory cells, to form a non-self-aligned gate stack structure without requiring line-to-line alignment of gate for the control gate and the floating gate, to solve the shortcomings of the prior art that the non-volatile memory must achieve line-to-line alignment of gates, thus reducing significantly the complexity of the manufacturing process, and the number of layers of photo masks required, in achieving production cost reduction.

In order to achieve the above-mentioned objective, the present invention provide a non-self-aligned non-volatile memory structure, mainly comprising a semiconductor substrate; a left floating gate memory cell and a right floating gate memory cell, a control gate, and a gate insulation layer.

The left floating gate memory cell and the right floating gate memory cell are formed on the semiconductor substrate, and the drains of the two floating gate memory cells are connected respectively to different voltage level, to achieve separate and independent applications.

The control gate is disposed over the left and right floating gate memory cells, to cover the floating gates of the two floating gate memory cells, hereby controlling two floating gates at the same time.

The gate insulation layer is disposed among the left floating gate memory cell, the right floating gate memory cell, and the control gate.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of a non-self-aligned non-volatile memory structure according to a first embodiment of the present invention;

FIG. 2 is a top view of a non-self-aligned non-volatile memory structure according to a first embodiment of the present invention;

FIG. 3 is a cross section view of a non-self-aligned non-volatile memory structure according to a second embodiment of the present invention;

FIG. 4 is a cross section view of a non-self-aligned non-volatile memory structure according to a third embodiment of the present invention;

FIG. 5 is a cross section view of a non-self-aligned non-volatile memory according to a fourth embodiment of the present invention; and

FIG. 6 is a top view of a non-self-aligned non-volatile memory structure according to a fourth embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

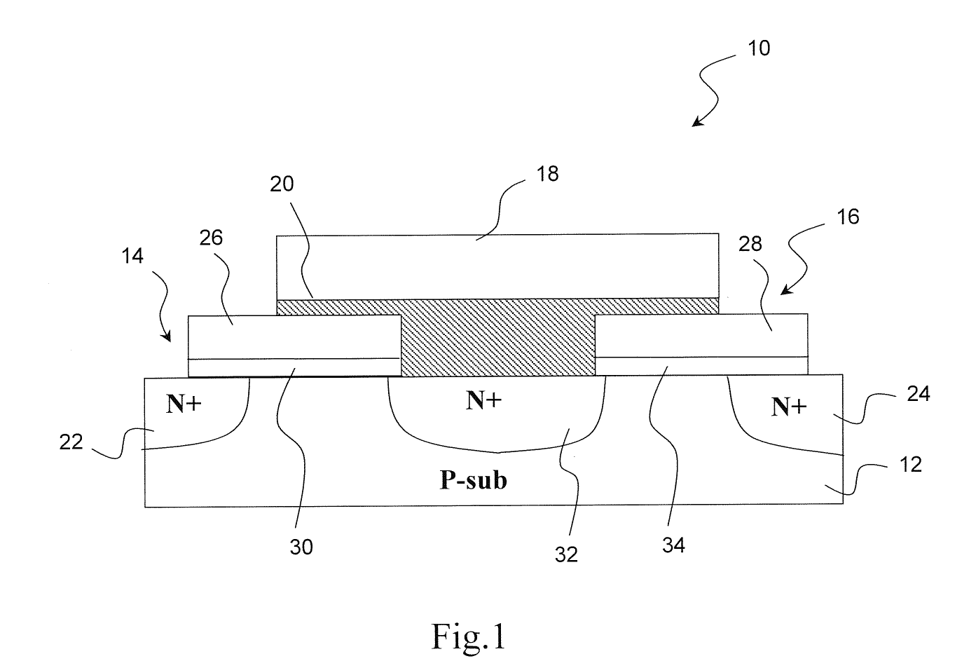

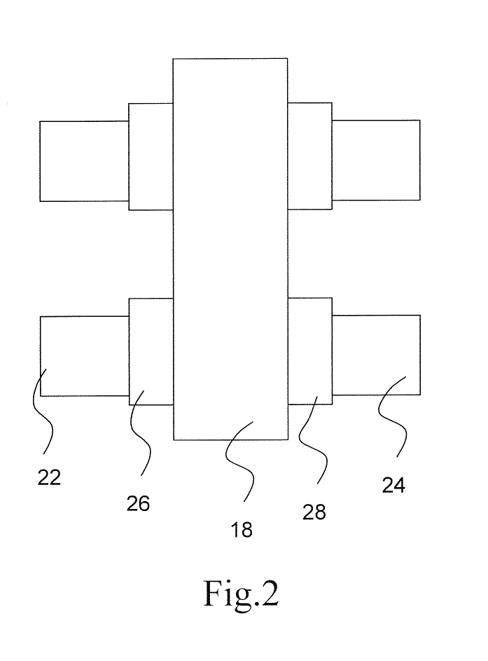

Refer to FIGS. 1 and 2 for a cross section view and a top view respectively of a non-self-aligned non-volatile memory structure according to a first embodiment of the present invention.

As shown in FIG. 1, the non-self-aligned non-volatile memory 10 of the present invention mainly includes: a semiconductor substrate 12, a left floating gate memory cell 14 and a right floating gate memory cell 16, a control gate 18, and a gate insulation layer 20.

The left floating gate memory cell 14 and the right floating gate memory cell 16 are formed on the semiconductor substrate 12, and the drain 22 of the left floating gate memory cell 14, and the drain 24 of the right floating gate memory cell 16 are connected to different voltage levels, to achieve separate and independent applications.

The control gate 18 is disposed over the left floating gate memory cell 14 and the right floating gate memory cell 16, such that the control gate 18 covers the floating gate 26 of the left floating gate memory cell 14 and the floating gate 28 of the right floating gate memory cell 16, so as to control the floating gates 26 and 28 simultaneously.

The gate insulation layer 20 is disposed among the left floating gate memory cell 14, the right floating gate memory cell 16, and the control gate 18, to achieve insulation.

In the descriptions mentioned above, the control gate 18 is made of polysilicon, while the gate insulation layer 20 is made of tetraethyl-ortho-silicate (TEOS).

The left floating gate memory cell 14 includes: a floating gate insulation layer 30 on the semiconductor substrate 12, a floating gate 26 on the floating gate insulation layer 30; and a drain 22 and a source 32. The drain 22 and the source 32 are disposed in the semiconductor substrate 12, and are located on both sides of the floating gate insulation layer 30; and are adjacent to the floating gate insulation layer 30.

Similarly, the right floating gate memory cell 16 includes: a floating gate insulation layer 34 on the semiconductor substrate 12, a floating gate 28 on the floating gate insulation layer 34; and a drain 24 and a source 32. The drain 24 and the source 32 are disposed in the semiconductor substrate 12, and are located on both sides of the floating gate insulation layer 34; and are adjacent to the floating gate insulation layer 34.

Moreover, as shown in FIG. 1, the source 32 of the left floating gate memory cell 14 and the right floating gate memory cell 16 are shared by both.

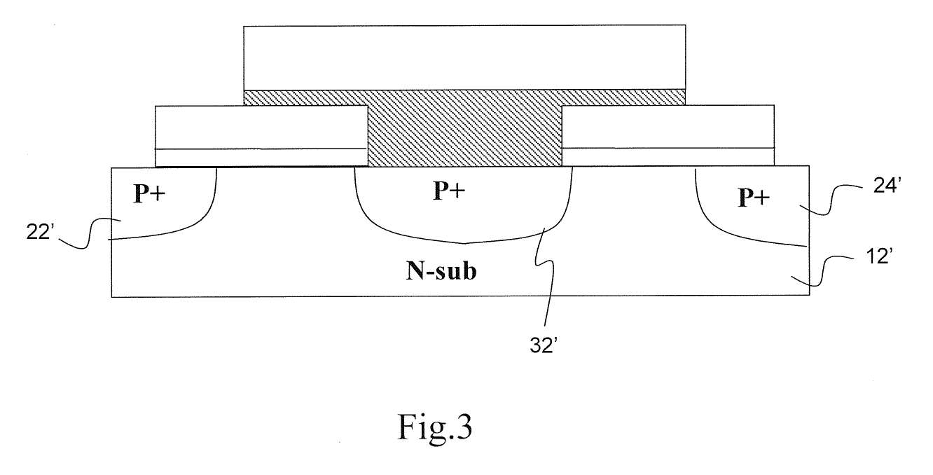

In addition, the conduction types of source and drain are opposite to that of the semiconductor substrate. By way of example, as shown in FIG. 1, when the semiconductor substrate 12 is a P-type semiconductor substrate (P-substrate), then the source 32 and drains 22 and 24 are of an N-doped semiconductor. Or alternatively, as shown in FIG. 3, when the semiconductor substrate 12′ is an N-type semiconductor substrate (N-substrate), then the source 32′ and drains 22′ and 24′ are of a P-doped semiconductor. The only difference of FIGS. 1 and 3 is that, the conduction types of source, drain, and semiconductor substrate are opposite, as such it will not be repeated here for brevity.

The left floating gate insulation layer 30 and right floating gate insulation layer 34 are made of silicon dioxide (SiO₂). Furthermore, the thickness of the gate insulation layer 20 is slightly more than that of the left floating gate insulation layer 30 and right floating gate insulation layer 34.

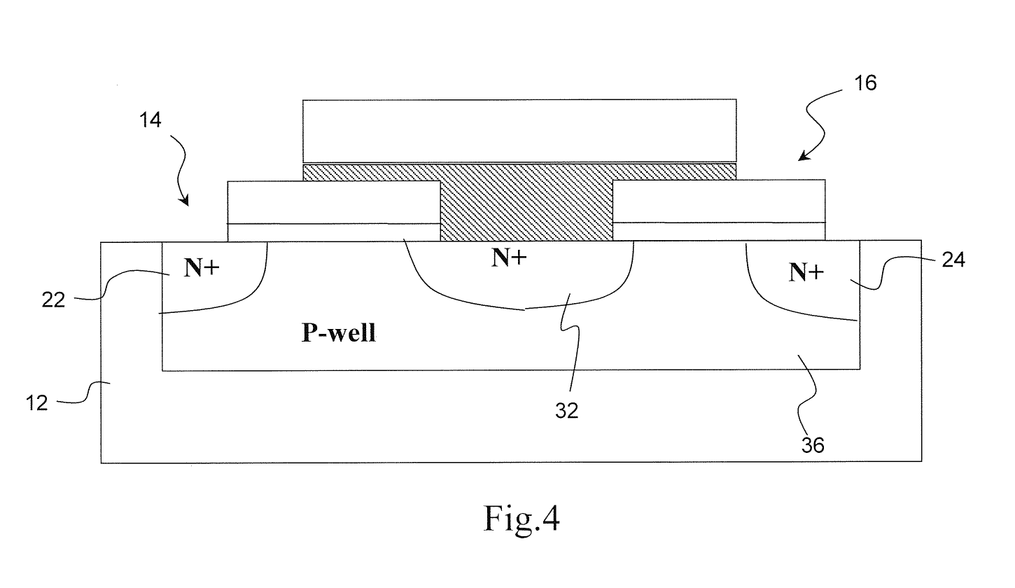

Refer to FIG. 4 for a cross section view of a non-self-aligned non-volatile memory structure according to a third embodiment of the present invention. As shown in FIG. 4, the semiconductor substrate 12 further includes a well region 36, such that the left floating gate memory cell 14 and the right floating gate memory cell 16 are located in the well region 36.

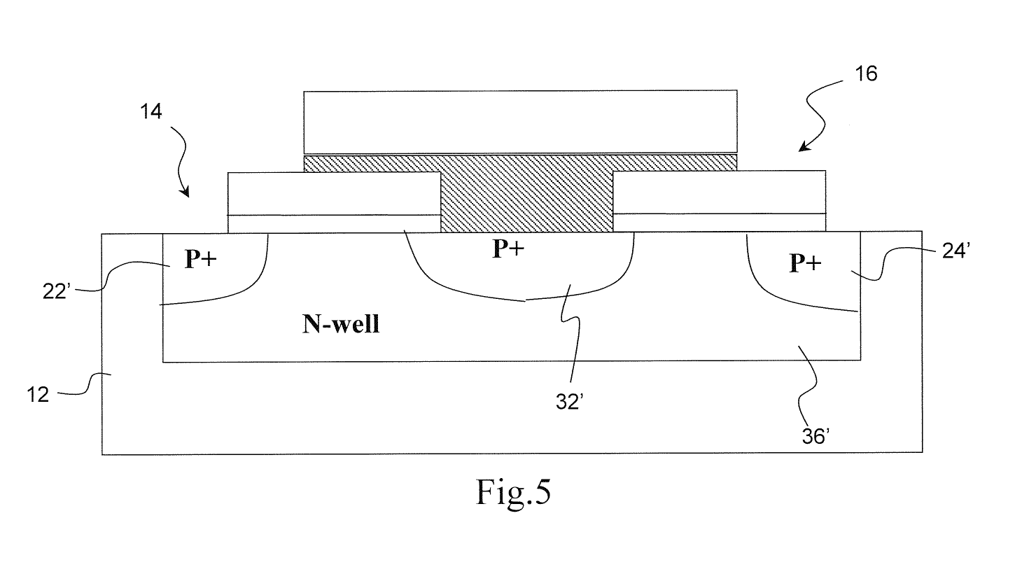

The conduction types of source and drain are opposite to that of the well regions. By way of example, as shown in FIG. 4, when the well region 36 is of a P type semiconductor, then the source 32 and drains 22 and 24 are of an N-doped semiconductor. Or alternatively, as shown in FIG. 5, when the well region 36 is of an N type semiconductor, then the source 32 and drains 22 and 24 are of a P-doped semiconductor. The only difference of FIGS. 5 and 4 is that, the conduction type of source, drain, and the well regions are opposite, as such it will not be repeated here for brevity.

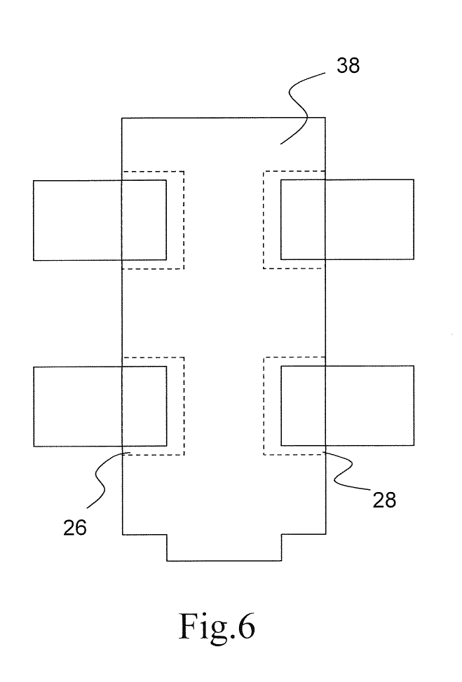

Finally, refer to FIG. 6 for a top view of a non-self-aligned non-volatile memory structure according to a fourth embodiment of the present invention. The difference of the fourth embodiment and the first embodiment of FIG. 2 is that, in FIG. 2, the overall appearance of the control gate 18 is a rectangle; while in FIG. 6, the overall appearance of the control gate 38 is of a saw-tooth shape. That means in FIG. 6, the left border of the control gate 38 not above the floating gate 26 of the left floating gate memory cell 14 is equal to or greater than the outer border of the floating gate 26, and the right border of the control gate 38 not above the floating gate 28 of the left floating gate memory cell 16 is equal to or greater than the outer border of the floating gate 28, thus presents outward protrusions.

Summing up the above, the present invention provides a non-self-aligned non-volatile memory structure, wherein, a control gate over a floating gate is used to cover two floating gate memory cells, to control two non-self-aligned floating gates simultaneously. Wherein, the drains of left and right floating gate memory cells are connected to different voltage levels respectively, in achieving separate and independent applications. In the present invention, the control gate and floating gate of non-volatile memory are formed into non-self-aligned structure, to solve the problem of the prior art that the non-volatile memory must achieve line-to-line alignment of gates, thus reducing significantly the complexity of manufacturing processes and the number of photo mask layers required, in realizing reduction of production cost.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A non-self-aligned non-volatile memory structure, comprising:
a semiconductor substrate;
a left floating gate memory cell and a right floating gate memory cell formed on said semiconductor substrate, drain of said left floating gate memory cell and drain of said right floating gate memory cell are connected to different voltage levels;
a control gate, disposed on said left floating gate memory cell and said right floating gate memory cell, and said control gate covers said floating gate of said left floating gate memory cell and said floating gate of said right floating gate memory cell, to control said floating gate of said left floating gate memory cell, and said floating gate of said right floating gate memory cell simultaneously; and
a gate insulation layer, provided among said left floating gate memory cell, said right floating gate memory cell, and said control gate.

2. The non-self-aligned non-volatile memory structure as claimed in claim 1, wherein the left border of said control gate not above said floating gate of said left floating gate memory cell is equal to or greater than the outer borders for said floating gate of said left floating gate memory cell, and the right border of said control gate not above said floating gate of said right floating gate memory cell is equal to or greater than the outer borders for said floating gate of said right floating gate memory cell.

3. The non-self-aligned non-volatile memory structure as claimed in claim 1, wherein said gate insulation layer is made of tetraethyl-ortho-silicate (TEOS).

4. The non-self-aligned non-volatile memory structure as claimed in claim 1, wherein said control gate is made of polysilicon.

5. The non-self-aligned non-volatile memory structure as claimed in claim 1, wherein said semiconductor substrate further includes a well region, and said left floating gate memory cell and said right floating gate memory cell are located in said well.

6. The non-self-aligned non-volatile memory structure as claimed in claim 1, wherein said left floating gate memory cell and said right floating gate memory cell each includes:
a floating gate insulation layer, located on said semiconductor substrate;
a floating gate, disposed on said gate insulation layer; and
a drain and a source, located in said semiconductor substrate, on both sides of said gate insulation layer, and are adjacent to said gate insulation layer.

7. The non-self-aligned non-volatile memory structure as claimed in claim 1, wherein said source of said right floating gate memory cell and said left floating gate memory cell are shared by both.

8. The non-self-aligned non-volatile memory structure as claimed in claim 6, wherein said source of said right floating gate memory cell and said left floating gate memory cell are shared by both.
